(19) United States
(12) Patent Application Publication
(10) Pub. No.: US 2016/0099086 A1
(43) Pub. Date: Apr. 7, 2016

(54) SUBSTRATE TRANSFER SYSTEM HAVING IONIZER

(71) Applicants: Jae-Wook LEE, Hwaseong-si (KR); Ho-Hyung JUNG, Hwaseong-si (KR); Kye-Hyun BAEK, Suwon-si (KR)

(72) Inventors: Jae-Wook LEE, Hwaseong-si (KR); Ho-Hyung JUNG, Hwaseong-si (KR); Kye-Hyun BAEK, Suwon-si (KR)

(21) Appl. No.: 14/729,419

(22) Filed: Jun. 3, 2015

(30) Foreign Application Priority Data
Oct. 2, 2014 (KR) 10-2014-0133322

(51) Int. Cl. G21K 5/08; H01L 21/66; H01L 21/67; H01L 21/68; H01J 37/28; H01L 21/677

(52) U.S. Cl. CPC G21K 5/08; H01J 37/28; H01L 21/67742; H01L 21/67253; H01L 21/68; H01L 22/12; H01J 2237/28

(57) ABSTRACT

A substrate transfer system includes a substrate transfer chamber between a substrate receiving port and a process chamber, the substrate transfer chamber providing a space for transferring a substrate between the substrate receiving port and the process chamber, and an ionizer within the substrate transfer chamber, the ionizer including a light source to irradiate electromagnetic waves having a predetermined radiation angle toward the substrate to eliminate static electricity of the substrate.

### CROSS-REFERENCE TO RELATED APPLICATION

Korean Patent Application No. 10-2014-0133322, filed on Oct. 2, 2014, in the Korean Intellectual Property Office, and entitled: “Substrate Transfer System Having Ionizer,” is incorporated by reference herein in its entirety.

### BACKGROUND

1. Field

Example embodiments relate to a substrate transfer system having an ionizer. More particularly, example embodiments relate to an ionizer for eliminating static electricity of a wafer during a semiconductor manufacturing process and a substrate transfer system having the same.

2. Description of the Related Art

An electrostatic charge generation on a wafer may be a potential risk factor in semiconductor fabrication processes. Such electrostatic charge generation may be minimized via an ionizer.

### SUMMARY

Example embodiments provide an ionizer capable of improving an antistatic efficiency. Example embodiments also provide a substrate transfer system including the ionizer.

According to example embodiments, a substrate transfer system includes a substrate transfer chamber between a substrate receiving port and a process chamber, the substrate transfer chamber providing a space for transferring a substrate between the substrate receiving port and the process chamber, and an ionizer within the substrate transfer chamber, the ionizer including a light source to irradiate electromagnetic waves having a predetermined radiation angle toward the substrate to eliminate static electricity of the substrate.

In example embodiments, the light source may include an X-ray tube for irradiating soft X-ray.

In example embodiments, the light source may be positioned over the center of the substrate.

In example embodiments, a distance of the light source from the substrate may be determined using trigonometry based on the radiation angle and a diameter of the substrate to irradiate the entire surface of the substrate.

In example embodiments, the distance (L) of the light source from the substrate may be calculated by an equation, L=D/2·tan(θ/2), where θ is the radiation angle and D is a diameter of the substrate.

In example embodiments, the radiation angle may be in the range of from about 110 degrees to about 140 degrees.

In example embodiments, the substrate transfer system may further include a shielding plate which surrounds the ionizer within the substrate transfer chamber.

In example embodiments, the substrate transfer system may further include a substrate aligner which is positioned within the substrate transfer chamber and aligns the substrate prior to transferring to the process chamber, and the ionizer may be positioned over the substrate aligner.

In example embodiments, the process chamber may be a measuring chamber for measuring a pattern formed on the substrate.

In example embodiments, the process chamber may include scanning electron microscope (SEM) for imaging the substrate.

In example embodiments, the ionizer may be controlled such that the ionizer is interlocked while the SEM operates.

In example embodiments, the ionizer may be controlled such that the ionizer is interlocked while a chamber door of the substrate transfer chamber operates.

In example embodiments, the substrate transfer system may further include a fan filter unit which is installed in an upper portion of the substrate transfer chamber and includes a blower fan and a filter for controlling a pressure and cleanliness of the substrate transfer chamber.

In example embodiments, the substrate transfer system may further include a transfer mechanism which transfers the substrate in the substrate transfer chamber.

According to example embodiments, a substrate transfer system includes a substrate transfer chamber disposed between a substrate receiving port and a process chamber and including a transfer mechanism for transferring a substrate therebetween, and an ionizer disposed within the substrate transfer chamber and including a light source which is positioned over the center of the substrate to irradiate X-ray having a predetermined radiation angle toward the substrate.

In example embodiments, the light source may include an X-ray tube for irradiating soft X-ray.

In example embodiments, a distance of the light source from the substrate may be determined using trigonometry based on the radiation angle and a diameter of the substrate to irradiate the entire surface of the substrate.

In example embodiments, the distance (L) of the light source from the substrate may be calculated by an equation, L=D/2·tan(θ/2), where θ is the radiation angle and D is a diameter of the substrate.

In example embodiments, the substrate transfer system may further include a shielding plate which surrounds the ionizer within the substrate transfer chamber.

In example embodiments, the substrate transfer system may further include a substrate aligner which is positioned within the substrate transfer chamber and aligns the substrate prior to transferring to the process chamber, and the ionizer may be positioned over the substrate aligner.

In example embodiments, the process chamber may be a measuring chamber for measuring a pattern formed on the substrate.

In example embodiments, the process chamber may include scanning electron microscope (SEM) for imaging the substrate.

In example embodiments, the ionizer may be controlled such that the ionizer is interlocked while the SEM operates.

In example embodiments, the ionizer may be controlled such that the ionizer is interlocked while a chamber door of the substrate transfer chamber operates.

According to example embodiments, an ionizer includes a light source positioned over the center of a wafer within a substrate transfer chamber to irradiate X-ray having a predetermined radiation angle toward the wafer, the substrate transfer chamber providing a space for transferring the wafer between a substrate receiving port and a process chamber. The minimum spacing distance of the light source from the wafer may be determined using trigonometry based on the radiation angle and a diameter of the wafer to irradiate the entire surface of the wafer.

In example embodiments, the minimum spacing distance (L) of the light source from the wafer may be calculated by an equation, L=D/2·tan(θ/2), where θ is the radiation angle and D is a diameter of the wafer.

In example embodiments, the light source may include an X-ray tube for irradiating soft X-ray.

In example embodiments, a body of the ionizer to which the X-ray tube is fixed may be mounted on a supporting member in the substrate transfer chamber by a fixing bracket.

In example embodiments, the ionizer may be positioned over a substrate aligner for aligning the wafer prior to transferring to the process chamber.

In example embodiments, the process chamber may be a measuring chamber for measuring a pattern formed on the wafer.

According to example embodiments, a substrate transfer system includes a substrate transfer chamber between a substrate receiving port and a process chamber, the substrate transfer including a space for accommodating a substrate, and an ionizer within the substrate transfer chamber, the ionizer including a light source aligned with a center of the substrate, and irradiating X-rays toward the substrate.

The light source may be an X-ray tube irradiating soft X-rays.

A distance between the light source and the substrate may equal a product of half a diameter of the substrate and a tangent of half an irradiation angle of the light source.

The substrate transfer system may further include a shielding plate surrounding the ionizer, the ionizer being enclosed by the shielding plate and sidewalls of the substrate transfer chamber.

The substrate may be on a stage, and the shielding plate surrounds the ionizer and the stage.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a substrate transfer system in accordance with example embodiments.

FIG. 2 illustrates a cross-sectional view of the substrate transfer system in FIG. 1.

FIG. 3 illustrates a plan view of an ionizer installed over a substrate aligner in FIG. 1.

FIG. 4 illustrates a partial perspective view of the ionizer in FIG. 3.

FIG. 5 illustrates a side view of the ionizer in FIG. 3.

FIG. 6 illustrates a view of an installation position of the ionizer in FIG. 3.

FIG. 7 illustrates a block diagram of a controller of the substrate transfer system in FIG. 1.

FIG. 8 illustrates a plan view of a substrate transfer system in accordance with example embodiments.

FIG. 9 illustrates a flowchart of a method of processing a substrate in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a.” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

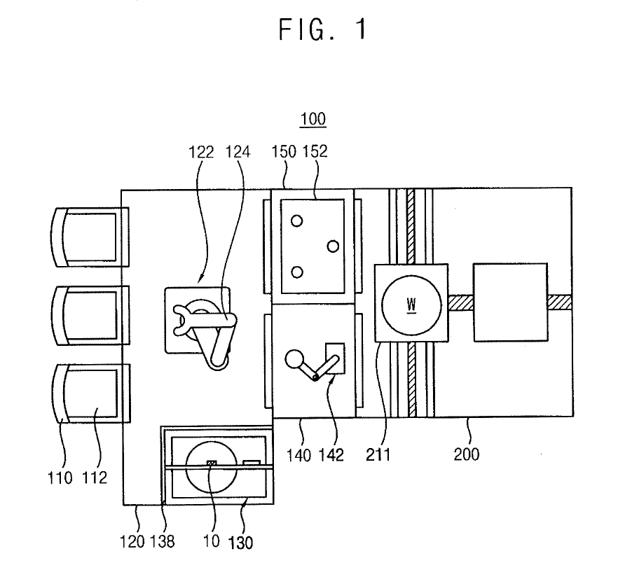

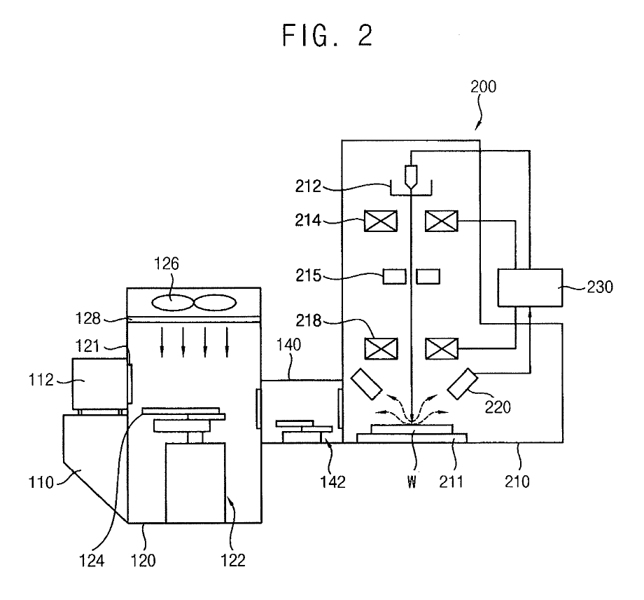

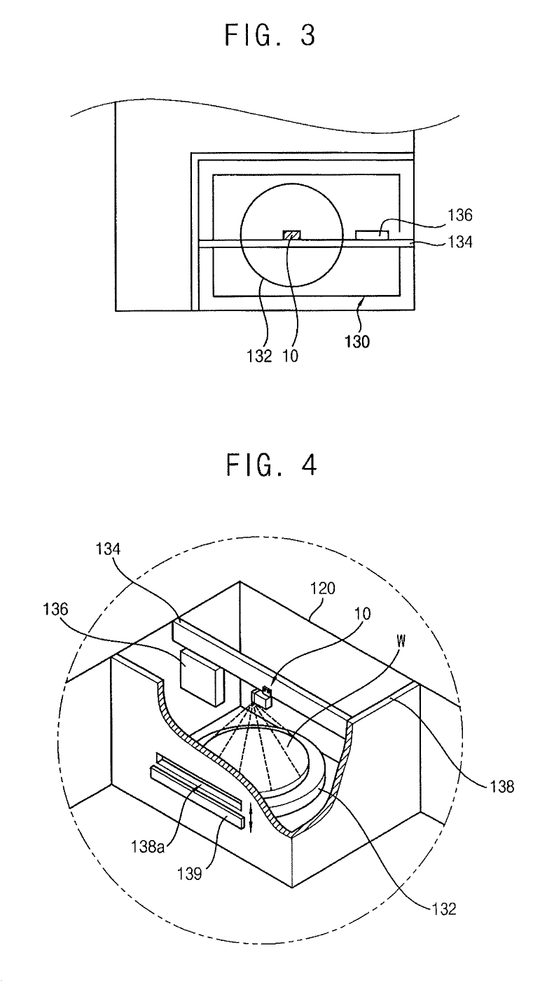

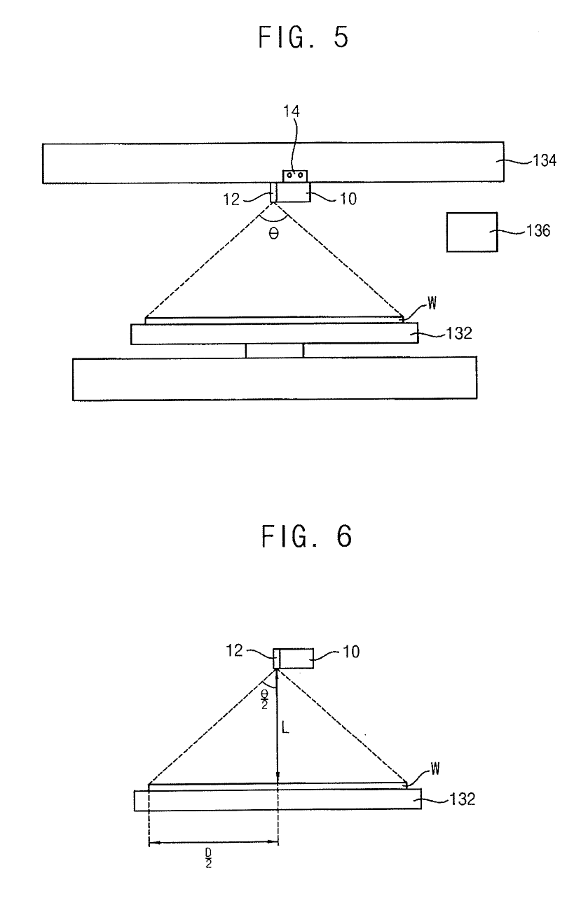

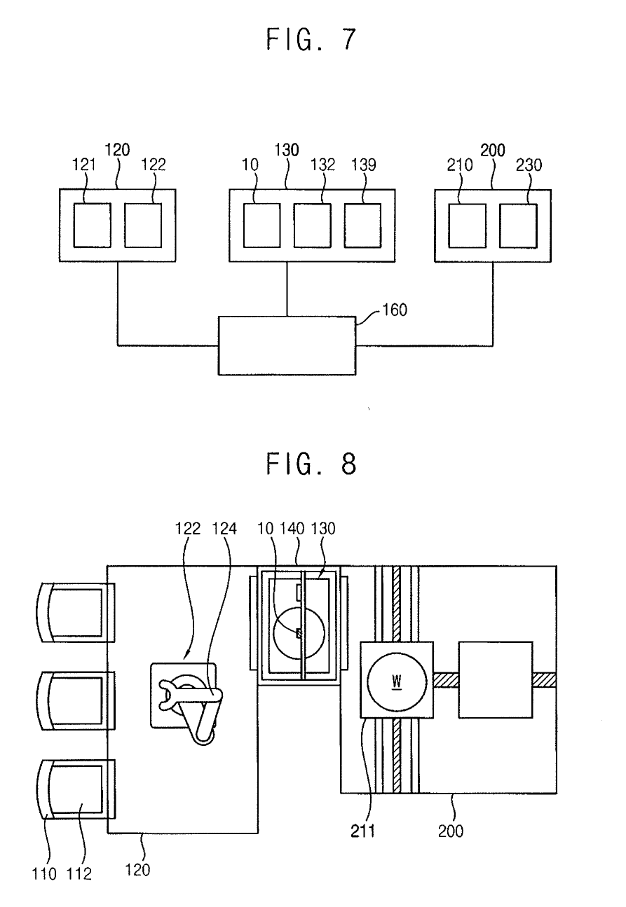

FIG. 1 is a plan view illustrating a substrate transfer system in accordance with example embodiments. FIG. 2 is a cross-sectional view illustrating the substrate transfer system in FIG. 1. FIG. 3 is a plan view illustrating an ionizer installed over a substrate aligner in FIG. 1. FIG. 4 is a partial perspective view illustrating the ionizer in FIG. 3. FIG. 5 is a side view illustrating the ionizer in FIG. 3. FIG. 6 is a view illustrating an installation position of the ionizer in FIG. 3. FIG. 7 is a block diagram illustrating a controller of the substrate transfer system in FIG. 1.

Referring to FIGS. 1 to 7, a substrate transfer system 100 may include a substrate transfer chamber 120 disposed between a substrate receiving port 110 and a process chamber 200 and providing a space for transferring a substrate therebetween, and an ionizer 10 disposed within the substrate transfer chamber 120 and configured to eliminate static electricity of the substrate. The substrate may include a semiconductor wafer W, a display panel substrate, etc.

In example embodiments, the substrate transfer system 100 may serve as equipment front end module (EFEM) which is disposed in front of a process equipment to transfer wafers from front open unified pod (FOUP) to the process equipment. The process equipment may include the process chamber 200 for performing a desired semiconductor process. For example, the process chamber 200 may perform a chemical vapor deposition process, an etching process, a measuring process, etc.

As illustrated in FIGS. 1 and 2, the substrate receiving port 110 may be positioned at a first side of the substrate transfer chamber 120. A wafer container (FOUP) 112 having wafers therein may be disposed on the substrate receiving port 110. The wafer container 112 may be transferred onto the substrate receiving port 110 by a transfer device such as overhead hoist transport (OHT).

The substrate transfer system 100 may include a transfer mechanism 122 which transfers wafers between the wafer container 112 and the process chamber 200. The transfer mechanism 122 may include a transfer arm 124 for gripping and transferring the wafer W from the wafer container 112.

In example embodiments, the substrate transfer system 100 may further include a fan filter unit for controlling pressure and cleanliness of the substrate transfer chamber 120. The fan filter unit may include a blower fan 126 installed on an upper wall of the substrate transfer chamber 120 to blow air downward and a filter 128 disposed under the blower fan 126 to filter contaminants out of the air. The substrate transfer chamber 120 with the fan filter unit may serve as a clean room having a desired cleanliness.

The process chamber 200 may be positioned at a second side of the substrate transfer chamber 120 opposite to the first side. The substrate transfer system 100 may further include a load lock chamber 140 and a buffer chamber 150 between the substrate transfer chamber 120 and the process chamber 200, as illustrated in FIG. 1. A holder 152 may be installed within the buffer chamber 150 to temporarily support the wafer. Accordingly, the wafer W in the wafer container 112 may be loaded into the process chamber 200 through the substrate transfer chamber 120 and the load lock chamber 140, and may be unloaded from the process chamber 200 back to the substrate receiving port 110 through the buffer chamber 150 and the substrate transfer chamber 120. As illustrated in FIGS. 1-2, the load lock chamber 140 may include a transfer mechanism 142.

As illustrated in FIG. 2, the process chamber 200 may be a measuring chamber for performing a measuring process. The process chamber 200 may include a scanning electron microscope (SEM) 210 for imaging the wafer W. A SEM image obtained by the SEM 210 may be used to measure a line width of a pattern formed on the wafer W.

In particular, the SEM 210 may include a stage 211 for supporting the wafer W, an electron gun 212 for generating a primary electron beam, an electron beam column having focusing lenses 214, a deflector 215 and an objective lens 218 for controlling a direction and a width of the primary electron beam and irradiating the electron beam onto the sample W, and a detector 220 for detecting electrons emitting from the wafer W.

For example, the wafer W may refer to a substrate formed of a semiconductor or non-semiconductor material. The wafer W may include one or more layers formed on the substrate. For example, such layers may include, but are be limited to, a resist, a dielectric material or a conductive material.

The detected electrons may be used to obtain a SEM image of the wafer W. The SEM image may be analyzed to measure the line width and the like of the pattern formed on the wafer W.

In example embodiments, the substrate transfer system 100 may further include a substrate aligner 130, as illustrated in FIG. 1. The substrate aligner 130 may be positioned within the substrate transfer chamber 120 and align the wafer W prior to transferring to the process chamber 200. For example, as illustrated in FIG. 1, the ionizer 10 may be positioned over the substrate aligner 130 to eliminate static electricity of the wafer W on the substrate aligner 130. In another example, the ionizer 10 may be positioned over the transfer arm 124 of the transfer mechanism 122 to eliminate static electricity of the wafer W gripped by the transfer arm 124.

As illustrated in FIGS. 1 and 3-5, the substrate aligner 130 may be disposed adjacent to a sidewall of the substrate transfer chamber 120. After a chamber door 121 is open (FIG. 2), the transfer arm 124 of the transfer mechanism 122 may grip and transfer the wafer W from the wafer container 112 to the substrate aligner 130. When the wafer W is transferred onto an aligning stage 132 of the substrate aligner 130 by the transfer mechanism 122, an aligning sensor 136 may detect a notch of the wafer W and the aligning stage 132 may rotate based on the detected information to align the wafer W.

In example embodiments, the ionizer 10 may be installed over the aligning stage 132 within the substrate transfer chamber 120 and may irradiate electromagnetic waves for generating ions toward the wafer W on the aligning stage 132 in order to eliminate static electricity of the wafer W.

In particular, the ionizer 10 may be installed to be positioned over the center of the wafer W. The ionizer 10 may include a light source which irradiates X-rays having a predetermined radiation angle (cone angle) (θ) toward the wafer W, as illustrated in FIG. 5. For example, as further illustrated in FIG. 5, the light source may include an X-ray tube 12 for irradiating soft X-rays. A body of the ionizer 10 may include a power module for supplying power to the X-ray tube 12. The X-ray tube 12 may be received in a housing of the body.

A supporting member 134 may be provided over the aligning stage 132 to install the ionizer 10 over the aligning stage 132. The ionizer 10 may be mounted on the supporting member 134, such that the ionizer 10 may be positioned over the center of the wafer W on the aligning stage 132. For example, the ionizer 10 may be fixed to the supporting member 134 by a fixing bracket 14.

Soft X-rays may spread out conically from the ionizer 10 toward the wafer W at a predetermined radiation angle (spread-out angle) from an irradiation hole of the X-ray tube 12. The soft X-rays emitted from the ionizer 10 may be electromagnetic waves having a wavelength ranging from several to several dozen angstroms and energies in the range of from several to several dozen keV. As the ionizer 10 directs soft X-rays toward the wafer W, gas atoms and gas molecules of a stable state within the irradiated region may be ionized to produce atomic gas ions and molecular gas ions with high concentration. Some of the produced ions having opposite polarity to the charged patterns within the irradiated region of the wafer W are thus allowed to bond with the charges on the charged patterns, resulting in the removal of static electricity.

The substrate aligner 130 may be disposed within the substrate transfer chamber 120 which serves as a down-flow type clean room. Accordingly, soft X-rays emitted from the ionizer 10 may be irradiated toward the wafer W on the aligning stage 132 by a down flow (shown as an arrow in FIG. 2).

The ions sprayed out by the ionizer 10 may have a high ion density and excellent ion balance. Thus, static electricity charged on an upper pattern as well as a lower pattern in a multi-layered structure on the wafer may be eliminated quickly and efficiently.

As illustrated in FIGS. 5 and 6, a distance (L) between the wafer W and the light source 12 may be determined using trigonometry from the radiation angle (θ) and a diameter (D) of the wafer W in order to irradiate the entire surface of the wafer W. The distance (L) of the light source 12 may be determined as minimum spacing distance by which the light source 12 is spaced apart from the wafer W. The spacing distance (L) of the light source 12 from the wafer W may be calculated by the following Equation 1, where θ is a radiation angle and D is a diameter of the wafer.

$$L = \frac{D \text{/} 2}{tan ( θ \text{/} 2 )} \qquad [ Equation 1 ]$$

For example, the radiation angle of the ionizer 10 may be in the range of from about 110 degrees to about 140 degrees. For example, when the radiation angle (θ) is 130 degrees and the diameter (D) of the wafer W is 300 mm, the spacing distance (L) of the light source 12 from the wafer W may be determined to be about 70 mm by Equation 1.

In example embodiments, as illustrated in FIG. 4, the substrate transfer system 100 may further include a shielding plate 138, which surrounds the ionizer 10 in order to provide an electromagnetic shield. The shielding plate 138 may be installed within the substrate transfer chamber 120 to surround the substrate aligner 130, as illustrated in FIG. 1. A slit 138a for loading/unloading the wafer W to/from the substrate aligner 130, and a gate 139 for opening/closing the slit 138a may be provided in the shielding plate 138, as illustrated in FIG. 4. The slit 138a and gate 139 may be in a sidewall of the shielding plate 138 facing the transfer mechanism 122.

For example, the shielding plate 138 may include metal, e.g., copper (Cu), aluminum (Al), lead (Pb) and iron (Fe), plastic, e.g., polyvinyl chloride (PVC), glass, etc. A thickness of the shielding plate 138 may be determined according to a material of the shielding plate 138. In case that the shielding plate 138 includes stainless steel, the shielding plate 138 may have a thickness of from about 0.1 mm to about 0.5 mm.

As illustrated in FIG. 7, the substrate transfer system 100 may include a controller 160 configured to control operations of the SEM 210 and a SEM controller 230 of the measuring chamber 200, operations of the chamber door 121 and the transfer mechanism 122, and operations of the substrate aligner 130 and the ionizer 10. The controller 160 may obtain information about operations of each of the elements in the substrate transfer system 100 and control each element based on the obtained information.

For example, the ionizer 10 may be controlled such that the ionizer 10 is operatively connected with the SEM 210. The measuring process in the measuring chamber 200 may be controlled with feedback-based operations of the ionizer 10. The ionizer 10 may be controlled such that the ionizer 10 is interlocked while the SEM 210 operates.

As mentioned above, the ionizer 10 may be installed to be positioned over, e.g., above, the center of the wafer W on the aligning stage 132 in the substrate transfer chamber 120, and may spray out soft X-rays having a predetermined radiation angle toward the wafer W. A distance of the ionizer 10 from the wafer W may be determined. e.g., adjusted, using trigonometry in accordance with the radiation angle and a diameter of the wafer W in order to irradiate the entire surface of the wafer W.

The ions generated by the ionizer 10 may have a high ion density and excellent ion balance. Thus, static electricity charged on an upper pattern as well as a lower pattern in a multi-layered structure on the wafer W may be eliminated rapidly and efficiently.

FIG. 8 is a plan view illustrating a substrate transfer system in accordance with example embodiments. The substrate transfer system in FIG. 8 is substantially the same as the substrate transfer system 100 described with reference to FIGS. 1 to 7, except an installation position of the ionizer. Thus, the same or like reference numerals will be used to refer to the same or like elements, and any repetitive explanation concerning the above elements will be omitted.

Referring to FIG. 8, the substrate aligner 130 may be disposed in the load lock chamber 140 between the substrate transfer chamber 120 and the process chamber 200. The ionizer 10 may be installed to be positioned over the substrate aligner 130 in the load lock chamber 140. In this case, the buffer chamber 152 of FIG. 1 will be omitted. The load lock chamber 140 and the substrate transfer chamber 120 may serve as a chamber for transferring a substrate, e.g., the wafer W, between the substrate receiving port 110 and the process chamber 200. The load lock chamber 140 may have a degree of vacuum lower than that of the substrate transfer chamber 120. Accordingly, the wafer W may be loaded/unloaded into/from the process chamber 200 through the load lock chamber 140.

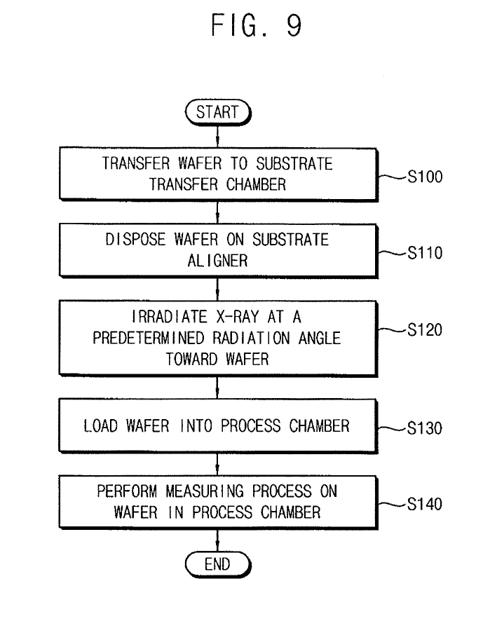

Hereinafter, a method of processing a substrate using the substrate transfer system 100 in FIG. 1 will be explained in detail with reference to FIG. 9. FIG. 9 is a flowchart illustrating a method of processing a substrate in accordance with example embodiments.

Referring to FIGS. 1, 2, and 9, first, the wafer W may be transferred into the substrate transfer chamber 120 (S100). In example embodiments, the wafer container 112 having wafers therein may be transferred onto the substrate receiving port 110 of the substrate transfer chamber 120. Semiconductor manufacturing processes may be performed on the wafers.

For example, semiconductor processes, e.g., a chemical vapor deposition process, an etching process, etc., may be performed on the wafer W to form a multi-layered structure having an upper pattern and a lower pattern. After performing the semiconductor processes, the wafer container 112 having the wafers therein may be transferred onto the substrate receiving port 110 by a transfer device, e.g., an overhead hoist transport (OHT). After the chamber door 121 is open, the transfer arm 124 of the transfer mechanism 122 may grip and transfer the wafer W from the wafer container 112 into the substrate transfer chamber 120.

Then, the wafer W may be disposed on the substrate aligner 130 in the substrate transfer chamber 120 (S110). That is, the wafer W may be transferred onto the substrate aligner 130 from the wafer container 112 by the transfer mechanism 122.

In detail, the gate 139 may move on the shielding plate 138 to open the slit 138a, and then, the transfer arm 124 may transfer the wafer W onto the aligning stage 132 through the slit 138a of the shielding plate 138. When the wafer W is loaded on the aligning stage 132 of the substrate aligner 130 by the transfer mechanism 122, the aligning sensor 136 may detect a notch of the wafer W, and the aligning stage 132 may rotate based on the detected information to align the wafer W.

Then, X-rays may be irradiated at a predetermined radiation angle toward the wafer W to eliminate static electricity of the wafer W (S120). That is, the ionizer may 10 may direct electromagnetic waves for generating electrostatic elimination ions toward the wafer W on the aligning stage 132 in order to eliminate static electricity of the wafer W.

The ionizer 10 may be installed to be positioned over the center of the wafer W. The ionizer 10 may include a light source which irradiates X-ray having a predetermined radiation angle (cone angle) toward the wafer W. For example, the light source may include the X-ray tube 12 for irradiating soft X-rays.

The ionizer 10 may irradiate soft X-rays which spreads out conically to have a predetermined radiation angle (spread-out angle) from an irradiation hole of the X-ray tube 12. The ionizer 10 may be installed to be spaced apart from the wafer W to irradiate the entire surface of the wafer W. The distance (L) of the ionizer 10 spaced apart from the wafer W may be determined using trigonometry based on the radiation angle (θ) and the diameter (D) of the wafer W.

The inner pressure and cleanliness of the substrate transfer chamber 120 may be kept by the fan filter unit. The blower fan 126 may be installed in an upper wall of the substrate transfer chamber 120 to generate a down flow, and the filter 128 may be disposed under the blower fan 126 to filter contaminants out of the air flowing into the substrate transfer chamber 120. Accordingly, the substrate transfer chamber 120 may serve as a down-flow type clean room.

Then, the neutralized wafer W may be loaded into the process chamber 200 through the load lock chamber 140 (S130). Then, a semiconductor process may be performed on the wafer W (S140).

A pattern formed on the wafer W may be measured within the process chamber 200. For example, the SEM 210 may be used to image the wafer W, and then, a SEM image obtained by the SEM 210 may be used to measure a line width of the pattern.

The ionizer 10 may be controlled such that the ionizer 10 is operatively connected with the SEM 210. The measuring process in the measuring chamber 200 may be controlled with feedback-based operations of the ionizer 10. The ionizer 10 may be controlled such that the ionizer 10 is interlocked while the SEM 210 operates.

The ionizer 10 may be controlled such that the ionizer 10 is operatively connected to substrate loading/unloading operations in the substrate transfer chamber 120. The ionizer 10 may be controlled such that the ionizer 10 is interlocked while the chamber door 121 of the substrate transfer chamber 120 operates.

Then, after completing the measuring process, the wafer W may be unloaded from the process chamber 200 through the holder 152, and may be transferred back to the substrate receiving port 110.

A semiconductor device. e.g., dynamic random-access memory (DRAM) and VNAND, formed using the substrate transfer system and method may be applied to computing systems. The computing system may be used for, e.g., a computer, a portable computer, a laptop computer, a personal digital assistant, a tablet, a mobile phone, a MP3 player, etc.

By way of summation and review, a conventional corona discharge type ionizer may be installed in a wafer transfer chamber for transferring a wafer to a process equipment to eliminate static electricity of the wafer. However, ions generated in the conventional ionizer may be lost before reaching the target, thereby deteriorate antistatic efficiency of the ionizer. Further, static electricity charged on a lower pattern in a multi-layered structure of the wafer may not be eliminated efficiently.

In contrast, an ionizer according to embodiments may be installed to be positioned over the center of a wafer in a substrate transfer chamber, and may direct soft X-rays having a predetermined radiation angle toward the wafer. A spacing distance of the ionizer from the wafer may be determined using trigonometry from the radiation angle and a diameter of the wafer in order to irradiate the entire surface of the wafer. The ions generated by the ionizer may have a high ion density and excellent ion balance. Thus, static electricity charged on an upper pattern, as well as a lower pattern, in a multi-layered structure on the wafer may be eliminated rapidly and efficiently.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A substrate transfer system, comprising:
a substrate transfer chamber between a substrate receiving port and a process chamber, the substrate transfer chamber providing a space for transferring a substrate between the substrate receiving port and the process chamber; and
an ionizer within the substrate transfer chamber, the ionizer including a light source to irradiate electromagnetic waves having a predetermined radiation angle toward the substrate to eliminate static electricity of the substrate.

2. The substrate transfer system as claimed in claim 1, wherein the light source includes an X-ray tube for irradiating soft X-rays.

3. The substrate transfer system as claimed in claim 1, wherein the light source is positioned over a center of the substrate.

4. The substrate transfer system as claimed in claim 3, wherein a distance of the light source from the substrate is determined based on trigonometric relationship of the predetermined radiation angle and a diameter of the substrate, to irradiate an entire surface of the substrate.

5. The substrate transfer system as claimed in claim 4, wherein the distance of the light source from the substrate is calculated by a following equation,
L=D/2·tan(θ/2),
where L is the distance, θ is the predetermined radiation angle, and D is the diameter of the substrate.

6. The substrate transfer system as claimed in claim 1, wherein the predetermined radiation angle is in a range of about 110 degrees to about 140 degrees.

7. The substrate transfer system as claimed in claim 1, further comprising a shielding plate surrounding the ionizer within the substrate transfer chamber.

8. The substrate transfer system as claimed in claim 1, further comprising a substrate aligner within the substrate transfer chamber, the substrate aligner aligning the substrate prior to transferring to the process chamber, and the ionizer being positioned over the substrate aligner.

9. The substrate transfer system as claimed in claim 1, wherein the process chamber is a measuring chamber for measuring a pattern on the substrate.

10. The substrate transfer system as claimed in claim 9, wherein the process chamber includes a scanning electron microscope (SEM) for imaging the substrate.

11. The substrate transfer system as claimed in claim 10, wherein the ionizer is interlocked, while the SEM operates.

12. The substrate transfer system as claimed in claim 1, wherein the ionizer is interlocked, while a chamber door of the substrate transfer chamber operates.

13. The substrate transfer system as claimed in claim 1, further comprising a fan filter unit in an upper portion of the substrate transfer chamber, the fan filter unit including a blower fan and a filter for controlling pressure and cleanliness of the substrate transfer chamber.

14. The substrate transfer system as claimed in claim 1, further comprising a transfer mechanism in the substrate transfer chamber, the transfer mechanism transferring the substrate.

15.-24. (canceled)

25. An ionizer, comprising:
a light source over a center of a wafer, the light source being within a substrate transfer chamber and irradiating X-rays at a predetermined radiation angle toward the wafer, and the substrate transfer chamber providing a space for transferring the wafer between a substrate receiving port and a process chamber,
wherein a minimum spacing distance of the light source from the wafer is based on trigonometric relationship of the predetermined radiation angle and a diameter of the wafer, to irradiate an entire surface of the substrate.

26. The ionizer as claimed in claim 25, wherein the minimum spacing distance of the light source from the wafer is calculated by a following equation,
L=D/2·tan(θ/2),
where L is the distance, θ is the predetermined radiation angle, and D is the diameter of the substrate.

27. The ionizer as claimed in claim 25, wherein the light source includes an X-ray tube for irradiating soft X-rays.

28. The ionizer as claimed in claim 27, wherein the ionizer includes a body and the X-ray tube connected to the body, the body being fixed to a supporting member in the substrate transfer chamber by a fixing bracket.

29. The ionizer as claimed in claim 25, wherein the ionizer is positioned over a substrate aligner for aligning the wafer prior to transferring to the process chamber.

30. The ionizer as claimed in claim 25, wherein the process chamber is a measuring chamber for measuring a pattern on the wafer.

31.-35. (canceled)
